(19) United States
(12) Patent Application Publication
(10) Pub. No.: US 2025/0160168 A1
(43) Pub. Date: May 15, 2025

(54) DISPLAY DEVICE, METHOD OF MANUFACTURING THE SAME, AND ELECTRONIC DEVICE INCLUDING THE SAME

(71) Applicant: Samsung Display Co., LTD., Yongin-si (KR)

(72) Inventors: JUNGSUN PARK, Yongin-si (KR); HWI KIM, Yongin-si (KR); JI-HEE SON, Yongin-si (KR); SEOULKI LEE, Yongin-si (KR); SEUNGJUN LEE, Yongin-si (KR); AREUM LEE, Yongin-si (KR); YEONHWA LEE, Yongin-si (KR); JOONGU LEE, Yongin-si (KR)

(21) Appl. No.: 18/934,377

(22) Filed: Nov. 1, 2024

(30) Foreign Application Priority Data
Nov. 13, 2023 (KR) 10-2023-0156529

(51) Int. Cl. H10K 59/80; H10K 59/12; H10K 59/122

(52) U.S. Cl. CPC H10K 59/80522; H10K 59/1201; H10K 59/122

(57) ABSTRACT

A display device includes: a first organic layer disposed on a substrate, and in which a first opening and a second opening spaced apart from the first opening are defined; an auxiliary electrode disposed on a portion of the first organic layer located between the first opening and the second opening and including a first conductive layer which contacts the portion of the first organic layer, a second conductive layer disposed on the first conductive layer, and a third conductive layer disposed on the second conductive layer and whose opposite ends are bent toward the substrate; a light-emitting layer disposed on the first organic layer and the auxiliary electrode, where portions of light-emitting layer are disconnected from each other by the auxiliary electrode; and a common electrode disposed on the light-emitting layer, where portions of the common electrode are disconnected from each other by the auxiliary electrode.

This application claims priority to Korean Patent Application No. 10-2023-0156529, filed on Nov. 13, 2023, and all the benefits accruing therefrom under 35 U.S.C. § 119, the content of which in its entirety is herein incorporated by reference.

### BACKGROUND

### 1. Field

Embodiments relate to a display device and a method of manufacturing the same. More particularly, the embodiments relate to the display device that provides visual information and the method of manufacturing the same

### 2. Description of the Related Art

The display device is a device that displays an image for providing visual information to a user. Among display devices, an organic light-emitting diode display device has recently attracted attention.

The organic light-emitting diode display device has self-luminous properties and, unlike a liquid crystal display device, do not require a separate light source, thus reducing thickness and weight. In addition, the organic light-emitting diode display device exhibits high-quality characteristics such as low power consumption, high luminance, and high response speed. Recently, as the organic light-emitting display diode device has become larger, there has been a problem with poor display quality due to a voltage drop (IR drop) phenomenon.

### SUMMARY

Embodiments provide a display device with improved display quality.

Embodiments provide a method of manufacturing the display device.

A display device according to an embodiment includes: a first organic layer disposed on a substrate, and in which a first opening and a second opening spaced apart from the first opening are defined; an auxiliary electrode disposed on a portion of the first organic layer located between the first opening and the second opening, and including a first conductive layer which contacts the portion of the first organic layer, a second conductive layer disposed on the first conductive layer, and a third conductive layer disposed on the second conductive layer and whose opposite ends are bent toward the substrate; a light-emitting layer disposed on the first organic layer and the auxiliary electrode, where portions of light-emitting layer are disconnected from each other by the auxiliary electrode; and a common electrode disposed on the light-emitting layer, where portions of the common electrode are disconnected from each other by the auxiliary electrode.

In an embodiment, a first inclination angle formed by a first tangent which is tangential to a first end of an upper surface of the third conductive layer and a plane parallel to a major surface of the substrate may be substantially equal to a second inclination angle formed by a second tangent which is tangential to a second end of an upper surface of the third conductive layer and the plane parallel to a major surface of the substrate.

In an embodiment, each of the first inclination angle and the second inclination angle may be about 10 degrees to about 150 degrees.

In an embodiment, the third conductive layer may form an undercut shape with the second conductive layer.

In an embodiment, the portions of the light-emitting layer may contact a portion of an upper surface of the first conductive layer and an upper surface of the third conductive layer, respectively, and may be spaced apart from each other with a side surface of the second conductive layer therebetween.

In an embodiment, the common electrode may contact a portion of the side surface of the second conductive layer, and may overlap the light-emitting layer which contacts the upper surface of the third conductive layer.

In an embodiment, an upper surface of the portion of the first organic layer, which contacts the first conductive layer, may have a curved surface

In an embodiment, each of the first conductive layer and the third conductive layer may have a curve line corresponding to the curved surface in a cross-sectional view.

In an embodiment, the first conductive layer, the second conductive layer, and third conductive layer may include different materials from each other.

In an embodiment, the display device may further include a transistor including an active layer disposed on the substrate, a gate electrode disposed on the active layer, and a source electrode and a drain electrode which contact the active layer and a second organic layer disposed on the transistor and spaced apart from the auxiliary electrode.

In an embodiment, the auxiliary electrode may be disposed in the same layer as each of the source electrode and the drain electrode, and may include the same material as each of the source electrode and the drain electrode.

A method of manufacturing the display device includes: forming an inorganic insulating layer on a substrate; forming a first organic layer, in which a first opening and a second opening spaced apart from each other are defined, on the inorganic insulating layer; forming a first conductive layer on the first organic layer; forming a second conductive layer on the first conductive layer; forming an auxiliary electrode by forming a third conductive layer, whose opposite ends are bent toward the substrate, on the second conductive layer; forming a light-emitting layer on the first organic layer and the auxiliary electrode, where portions of light-emitting layer are disconnected from each other by the auxiliary electrode, and forming a common electrode on the light-emitting layer, where portions of the common electrode are disconnected from each other by the auxiliary electrode.

In an embodiment, the forming of the first organic layer may include forming a preliminary organic layer on the inorganic insulating layer, exposing the first preliminary organic layer to a light, and forming the first opening and the second opening by removing a portion of the preliminary organic layer through a developer.

In an embodiment, the forming of the auxiliary electrode may include: forming a metal layer, which fills the first opening and the second opening, on the first organic layer; and forming a source electrode, a drain electrode, and the auxiliary electrode simultaneously on the first organic layer by removing a portion of the metal layer.

In an embodiment, the forming of the metal layer may include forming a first metal layer, which fills the first opening and the second opening, on the first organic layer, forming a second metal layer including a material different from the first metal layer on the first metal layer, and forming a third metal layer including a material different from the second metal layer on the second metal layer

In an embodiment, the first conductive layer may be formed by removing a portion of the first metal layer, the second conductive layer may be formed by removing a portion of the second metal layer, and the third conductive layer may be formed by removing a portion of the third metal layer.

In an embodiment, the forming of the light-emitting layer may include depositing a light-emitting material forming the light-emitting layer in a first deposition direction having a first inclination angle with respect to a plane parallel to a major surface of the substrate, and the forming of the common electrode may include depositing a metal material forming the common electrode in a second deposition direction having a second inclination angle with respect to the plane parallel to the major surface of the substrate.

In an embodiment, a line, which extends from one end among the opposite ends of an upper surface of the third conductive layer and parallel to the first deposition direction, may not intersect with a side surface of the second conductive layer

In an embodiment, a line, which extends from one end among the opposite ends of an upper surface of the third conductive layer and parallel to the second deposition direction, may intersect with a side surface of the second conductive layer.

In an embodiment, the first inclination angle may be larger than the second inclination angle.

In the display device according to embodiments, the display device may include an auxiliary electrode including a first conductive layer, a second conductive layer disposed on the first conductive layer, and a third conductive layer disposed on the second conductive layer. In addition, an upper surface of the first conductive layer and a side surface of the second conductive layer may contact a common electrode. Accordingly, since the auxiliary electrode may assist in a role of a power line to which a first power voltage is applied, a voltage drop (IR drop) phenomenon may decrease and a display quality may be improved.

In the method of manufacturing the display device according to embodiments, by adjusting an incident angle of a metal material used for deposition of the third conductive layer whose opposite ends are bent toward the substrate and the common electrode, the auxiliary electrode may be manufactured without a separate additional process. Accordingly, a process time may be shortened and a process cost may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of present disclosure.

FIG. 2 is a cross-sectional view taken along line I-I′.

FIG. 3 is an enlarged cross-sectional view of area A in FIG. 2.

FIGS. 4, 5, 6, 7, 8, 9, 10, 11, 12, 13, 14, 15, 16, 17, 18, 19, 20, 21, 22, and 23 are cross-sectional views illustrating a method of manufacturing the display device in FIG. 1.

FIG. 24 is a cross-sectional view illustrating an example of an auxiliary electrode in FIG. 2.

FIG. 25 is a cross-sectional view illustrating another example of an auxiliary electrode in FIG. 2.

FIG. 26 is a block diagram illustrating an electronic device according to an embodiment.

### DETAILED DESCRIPTION

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “substantially equal” can mean within one or more standard deviations, or within ±10%, 5% or 2% of the stated value.

Hereinafter, a display device and a method of manufacturing the same in accordance with embodiments will be described in more detail with reference to the accompanying drawings. The same reference numerals are used for the same components in the drawings, and redundant descriptions of the same components will be omitted.

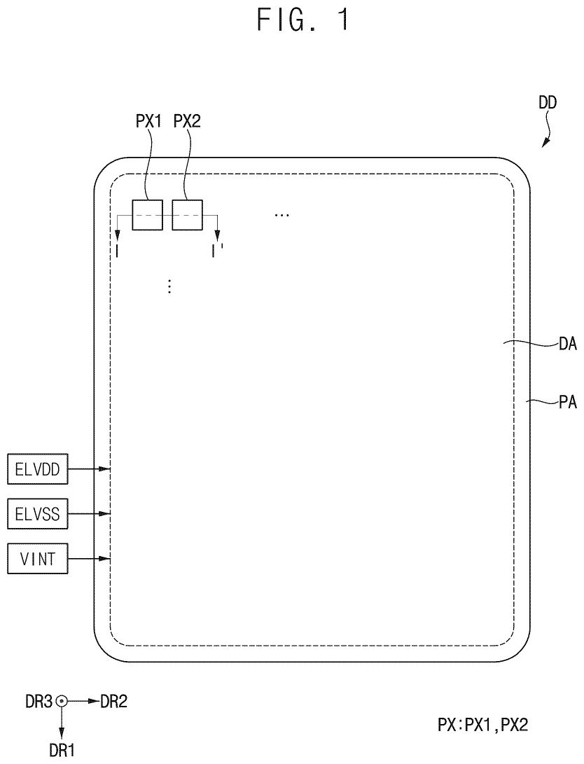

FIG. 1 is a plan view illustrating a display device according to an embodiment of the present disclosure.

Referring to FIG. 1, a display device DD according to an embodiment of the present disclosure may include a display area and a non-display area. The non-display area may be located adjacent to the display area. For example, the non-display area may surround the display area entirely.

In this specification, a plane may be defined by a first direction DR1 and a second direction DR2. For example, the second direction DR2 may be perpendicular to the first direction DR1. In addition, the third direction DR3 may be perpendicular to the plane.

The display area may be defined as an area generating an image. A plurality of pixel areas PX may be disposed in the display area. For example, the pixel areas PX may be arranged along the first direction and the second direction. For example, the first pixel area PX1 and the second pixel area PX2 may be adjacent to each other. Specifically, the first pixel area PX1 and the second pixel area PX2 may be adjacent to each other in the second direction DR2.

The first pixel area PX1 may be an area including a plurality of sub-pixels which emit a light. The plurality of sub-pixels may emit a first light, a second light, and a third light which are different colors to each other. In an embodiment, the first light may be a red light, the second light may be a green light, and the third light may be a blue light. However, the present disclosure may not be limited to this. For example, the first pixel area PX1 may be an area including a plurality of sub-pixels which emit a yellow light, a cyan light, and a magenta light. The second pixel area PX2 may be substantially equal to the first pixel area PX1.

The non-display area PA may be defined as an area which does not generate an image. A plurality of power lines may be disposed in the non-display area PA. The power lines may supply power voltages to the sub-pixels. The power voltages may include a first power voltage ELVSS, a second power voltage ELVDD, an initialization voltage VINT, and the like. In addition, a driver for driving the display device DD may be disposed in the non-display area. The driver may be electrically connected to the power lines.

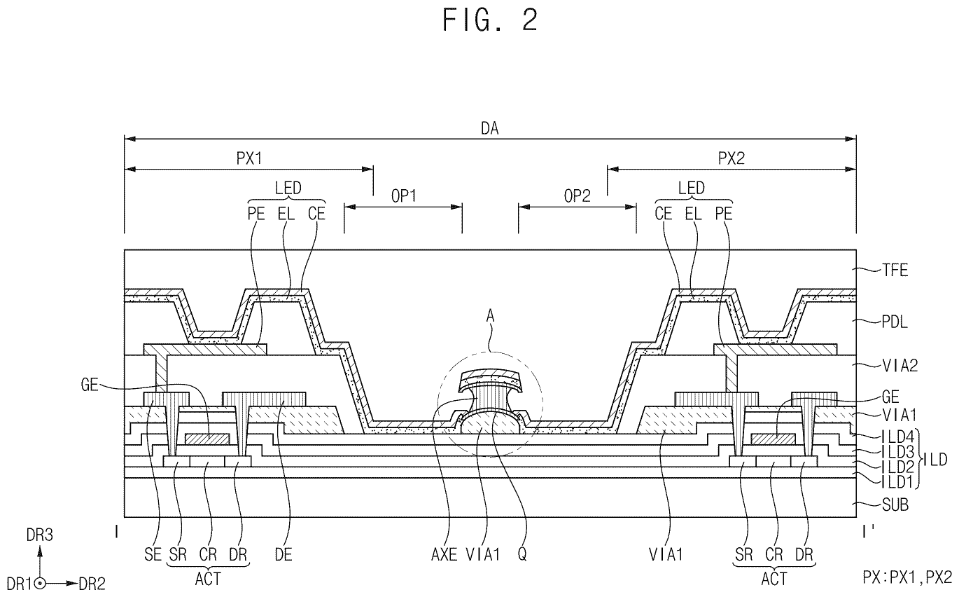

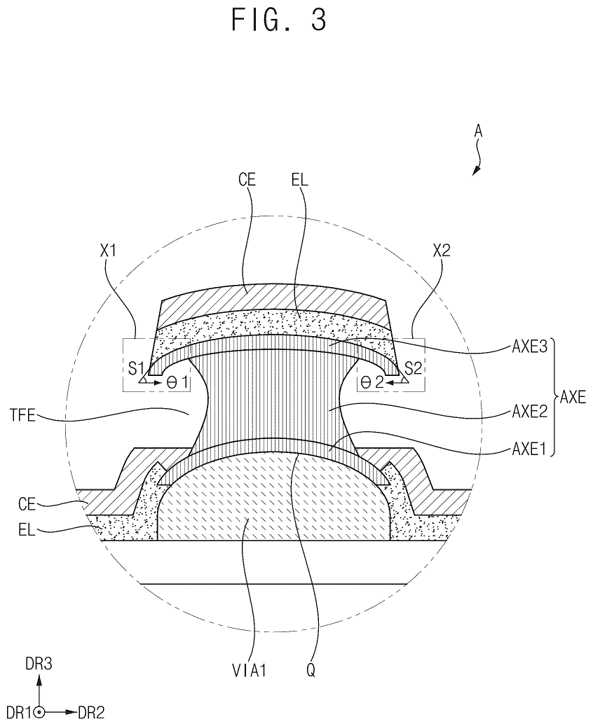

FIG. 2 is a cross-sectional view taken along line I-I′. FIG. 3 is an enlarged cross-sectional view of area A in FIG. 2.

Referring to FIGS. 2 and 3, the display device (e.g., the display device DD in FIG. 1) may include a substrate SUB, a first inorganic insulating layer ILD1, an active layer ACT, a second inorganic insulating layer ILD2, a gate electrode GE, a third inorganic insulating layer ILD3, a fourth inorganic insulating layer ILD4, a first organic layer VIA1, an auxiliary electrode AXE, a source electrode SE, a drain electrode DE, a second organic layer VIA2, a pixel electrode PE, a pixel-defining layer PDL, a light-emitting layer EL, a common electrode CE, and an encapsulation layer TFE.

The substrate SUB may be a transparent insulating substrate. For example, the substrate SUB may include a glass, a quartz, a plastic, and the like. These may be used in alone or in combination with each other.

The first inorganic insulating layer ILD1 may be disposed on the substrate SUB. The first inorganic insulating layer ILD1 may protect impurities from diffusing from the substrate SUB to the active layer ACT.

The first inorganic insulating layer ILD1 may include an inorganic material. The inorganic material may include a silicon nitride, a silicon oxide, a silicon oxynitride and the like. These may be used in alone or in combination with each other.

The active layer ACT may be disposed on the first inorganic insulating layer ILD1. The active layer ACT may include an amorphous silicon, or a polycrystal silicon, or a oxide semiconductor. The active layer ACT may include a source region SR, a drain region DR, and a channel region CR disposed between the source SR and the drain region DR, and the source SR, the drain region DR, and the channel region CR may be doped by impurities.

The second inorganic insulating layer ILD2 may be disposed on the first inorganic insulating layer ILD1. The second inorganic insulating layer ILD2 may cover the active layer ACT on the first inorganic insulating layer ILD1. For example, the second inorganic insulating layer ILD2 may have a substantially uniform thickness along a profile of the active layer ACT. Alternatively, the second inorganic insulating layer ILD2 may cover the active layer ACT sufficiently, may not generate a step surround the active layer ACT, and may have a substantially flat upper surface.

The second inorganic insulating layer ILD2 may include an inorganic material. The inorganic material may include a silicon nitride, a silicon oxide, a silicon oxynitride and the like. These may be used in alone or in combination with each other.

The gate electrode GE may be disposed on the second inorganic insulating layer ILD2. The gate electrode GE may overlap the channel region CR of the active layer ACT. The gate electrode GE may include a metal, an alloy, a conductive metal oxide, a transparent conductive material, and the like.

The third inorganic insulating layer ILD3 may be disposed on the second inorganic insulating layer ILD2. The third inorganic insulating layer ILD3 may cover the gate electrode GE on the second inorganic insulating layer ILD2. For example, the third inorganic insulating layer ILD3 may have a substantially uniform thickness along a profile of the gate electrode GE. Alternatively, the third inorganic insulating layer ILD3 may cover the gate electrode GE sufficiently, may not generate a step surround the gate electrode GE, and may have a substantially flat upper surface.

The third inorganic insulating layer ILD3 may include an inorganic material. The inorganic material may include a silicon nitride, a silicon oxide, a silicon oxynitride and the like. These may be used in alone or in combination with each other.

The fourth inorganic insulating layer ILD4 may be disposed on the third inorganic insulating layer ILD3. The fourth inorganic insulating layer ILD4 may have a substantially uniform thickness along a profile of third inorganic insulating layer ILD3. Alternatively, the fourth inorganic insulating layer ILD4 may cover the third inorganic insulating layer ILD3 sufficiently, may not generate a step surround the gate electrode GE, and may have a substantially flat upper surface.

The fourth inorganic insulating layer ILD4 may include an inorganic material. The inorganic material may include a silicon nitride, a silicon oxide, a silicon oxynitride and the like. These may be used in alone or in combination with each other.

In this specification, an inorganic insulating layer ILD may be defined by the first, second, third, and fourth inorganic insulating layers ILD1, ILD2, ILD3, and ILD4.

The first organic layer VIA1 may be disposed on the inorganic insulating layer ILD. For example, the first organic layer VIA1 may be disposed on the fourth inorganic insulating layer ILD4. The first organic layer VIA1 may have a substantially flat upper surface by not generating a step surround the gate electrode GE. The first organic layer VIA1 may include an organic insulating material such as a polyimide. However the present disclosure may not be limited to this.

A first opening OP1 and a second opening OP2 exposing a portion of an upper surface of the inorganic insulating layer ILD may be defined in the first organic layer VIA1. The first opening OP1 and the second opening OP2 may be spaced apart from each other. In an embodiment, an upper surface Q of a portion of the first organic layer VIA1 disposed between the first opening OP1 and the second opening OP2 may have a curved surface.

The auxiliary electrode AXE may be disposed on the first organic layer VIA1. Specifically, the auxiliary electrode AXE may be disposed on a portion of the first organic layer VIA1 disposed between the first opening OP1 and the second opening OP2.

At least one of the auxiliary electrode AXE may be disposed between two pixel areas which are adjacent to each other among the pixel areas PX. For example, the auxiliary electrode AXE may be disposed between the first pixel area PX1 and the second pixel area PX2.

The auxiliary electrode AXE may include a first conductive layer AXE1, a second conductive layer AXE2, and a third conductive layer AXE3. The first conductive layer AXE1 may contact the first organic layer VIA1. For example, the first conductive layer AXE1 may contact the upper surface Q of the portion of the first organic layer VIA1 disposed between the first opening OP1 and second opening OP2.

Opposite ends of the first conductive layer AXE1 may be bent toward the substrate SUB. For example, the upper surface Q which is a portion of the first organic layer VIA1 contacting the first conductive layer AXE1 may have a curved surface. Accordingly, the first conductive layer AXE1 may have a curved surface corresponding to the curved surface of the upper surface Q in a cross-sectional view. However, the present disclosure may not be limited to this, and in another embodiment, the first conductive layer AXE1 may have straight line in cross-sectional view, and opposite ends of the first conductive layer AXE1 may be bent.

The first conductive layer AXE1 may include a conductive material. For example, the first conductive material include a titanium, a copper, a indium tin oxide, a indium zinc oxide, and the like. These may be used in alone or in combination with each other.

The second conductive layer AXE2 may be disposed on the first conductive layer AXE1. The second conductive layer AXE2 may contact an upper surface of the first conductive layer AXE1 and a rear surface of the third conductive layer AXE3. In an embodiment, the second conductive layer AXE2 may have an undercut shape with the third conductive layer AXE3. For example, an average width of the second conductive layer AXE2 in the second direction DR2 may be smaller than an average width of the third conductive layer AXE3 in the second direction DR2.

In an embodiment, the second conductive layer AXE2 may include a conductive material. For example, the conductive material may include an aluminum, a indium tin oxide, a indium zinc oxide, and the like. These may be used alone in alone and in combination with each other. In an embodiment, the second conductive layer AXE2 may include a material different from the first conductive layer AXE1.

The third conductive layer AXE3 may be disposed on the second conductive layer AXE2. Opposite ends of the third conductive layer AXE3 may be bent toward the substrate SUB. The opposite ends may include a first end X1 and a second end X2.

At the first end X1 of an upper surface of the third conductive layer AXE3, a first tangent S1 which is tangential to the first end X1 may be defined. In addition, a first inclination angle θ1 may be defined as an angle formed by the first tangent S1 and a plane parallel to a major surface of the substrate SUB. For example, the first inclination angle θ1 may be an angle formed by the first tangent S1 and the second direction DR2.

At the second end X2 of an upper surface of the third conductive layer AXE3, a second tangent S2 which is tangential to the second end X2 may be defined. In addition, a second inclination angle θ2 may be defined as an angle formed by the second tangent S2 and a plane parallel to a major surface of the substrate SUB. For example, the second inclination angle θ2 may be an angle formed by the second tangent S2 and a direction opposite to the second direction DR2.

In an embodiment, the first inclination angle θ1 may be about 10 degrees or more and about 150 degrees or less. Preferably, the first inclination angle θ1 may be about 70 degrees or more and about 120 degrees or less. In an embodiment, the second inclination angle 74 2 1 may be 10 degrees or more and 150 degrees or less. Preferably, the second inclination angle θ2 may be about 70 degrees or more and about 120 degrees or less. In addition, the first end X1 and the second end X2 of the third conductive layer AXE3 may be bent toward the second conductive layer AXE2 in the case that each of the first inclination angle θ1 and the second inclination angle θ2 is more than about 90 degrees.

In an embodiment, the first inclination angle θ1 and the second inclination angle θ2 may be substantially equal to each other. For example, an angle of each of the first inclination angle θ1 and the second inclination angle θ2 may be equal in a range from about 10 degrees to about 150 degrees. However, the present disclosure may not be limited to this, and the first inclination angle θ1 and the second inclination angle θ2 may be different from each other during a manufacturing process.

In an embodiment, the third conductive layer AXE3 may include a conductive material. For example, the conductive material include a titanium, a copper, a indium tin oxide, a indium zinc oxide, and the like. These may be used in alone or in combination with each other.

In an embodiment, the third conductive layer AXE3 may include the same material as the first conductive layer AXE1. In addition, in the embodiment, the third conductive layer AXE3 may include a material different from the second conductive layer AXE1. For example, the first conductive material AXE1 may include a titanium, the second conductive material AXE2 may include a aluminum, and the third conductive material AXE3 may include a titanium. However, the present disclosure may not be limited to this.

Alternatively, the third conductive layer AXE 3 may include a material different from the first conductive layer AXE1. In this case, the second conductive layer AXE2 may include a material different from each of the first and third conductive layers AXE1 and AXE3. For example, the first conductive material AXE1 may include a indium tin oxide, the second conductive material AXE2 may include an aluminum, and the third conductive material AXE3 may include a titanium. However, the present disclosure may not be limited to this.

In an embodiment, the third conductive layer AXE 3 may have a curved surface in a cross-sectional view. However, the present disclosure may not be limited to this, and the third conductive layer AXE 3 may have a straight line in a cross-sectional view, and each of the first end X1 and the second end X2 of the third conductive layer AXE 3 may be bent toward the substrate SUB.

The source and drain electrodes SE and DE may be disposed on the first organic layer VIA1. The source and the drain electrodes SE and DE may contact the active layer ACT through a contact hole penetrating the first organic layer VIA1 and the organic layer ILD. For example, the source electrode SE may be contact the source region SR through the contact hole penetrating the first organic layer VIA1 and the organic layer ILD. The drain electrode DE may contact the drain region DR through the contact hole penetrating the first organic layer VIA1 and the organic layer ILD. Accordingly, the active layer ACT, the gate electrode GE, the source electrode SE, and the drain electrode DE may form a transistor.

The source and drain electrodes SE and DE may include a conductive material. For example, the conductive material may include a titanium, a aluminum, a copper, a indium tin oxide, a indium zinc oxide, and the like. These may be used in alone or in combination with each other.

In an embodiment, each of the source and drain electrodes SE and DE a multi-layer structure including metal materials. For example, each of the source and drain electrodes SE and DE may have a three layer structure corresponding to the first, second, and third conductive layers AXE1, AXE2, and AXE3.

In an embodiment, each of the source and drain electrodes SE and DE may include the same material as the auxiliary electrode AXE. Each of the source and drain electrodes SE and DE may be disposed in the same layer as the auxiliary electrode AXE. Each of the source and drain electrodes SE and DE may be formed by the same process as the auxiliary electrode AXE

The second organic layer VIA2 may be disposed on the source and drain electrodes SE and DE. The second organic layer VIA2 may cover a portion of a side surface of the first organic layer VIA1. However, the second organic layer VIA2 may be spaced apart from the auxiliary electrode AXE. In addition, the second organic layer VIA2 may overlap a portion of each of the first and second openings OP1 and OP2. For example, the second organic layer VIA2 may fill a portion of the first opening OP1 which is not adjacent to the auxiliary electrode AXE. In addition, the second organic layer VIA2 may fill a portion of the second opening OP2 which is not adjacent to the auxiliary electrode AXE.

The second organic layer VIA2 may have a substantially flat surface. The second organic layer VIA2 may include a organic insulating material such as a polyimide. However, the present disclosure may not be limited to this.

The pixel electrode PE may be disposed on the second organic layer VIA2. In an embodiment, the pixel electrode PE may contact the source electrode SE. Alternatively, the pixel electrode PE may contact the drain electrode DE. The pixel electrode PE may include a metal, an alloy, a conductive metal oxide, a conductive metal nitride, a transparent conductive material, and the like. These may be used in alone or in combination with each other. For example, the pixel electrode PE may include a silver and a indium tin oxide.

The pixel-defining layer PDL may be disposed on the second organic layer VIA2. The pixel-defining layer PDL may cover partially the pixel electrode PE. In addition, an opening exposing at least a portion of the pixel electrode PE may be defined in the pixel-defining layer PDL. For example, the opening in the pixel-defining layer PDL may exposed a center portion of the pixel electrode PE, and cover an edge portion of the pixel electrode PE. The pixel-defining layer PDL may include the same material as the first and second organic layers VIA1 and VIA2. For example, the pixel-defining layer PDL may include a organic insulating layer such as a polyimide.

The light-emitting layer EL may be disposed on the pixel-defining layer PDL. The light-emitting layer EL may be disposed on the pixel electrode PE exposed by the opening in the pixel-defining layer PDL. The light-emitting layer EL may include an organic light-emitting material. For example, the organic light-emitting material may include a low-molecular organic compound or a high-molecular organic compound. However, the present disclosure may not be limited to this, and the light-emitting layer EL may include a material like quantum dot and the like.

The light-emitting layer EL may be disposed on one surface of the first conductive layer AXE1. For example, the light-emitting layer EL may be extended until a portion of the first conductive layer AXE1 which contacts the second conductive layer AXE2, on the one surface, in the second direction DR2.

In an embodiment, the light-emitting layer EL may be spaced apart from a side surface of the second conductive layer AXE2. Alternatively, the light-emitting layer EL may contact a lower portion of the side surface of the second conductive layer AXE2 adjacent to the first conductive layer AXE1. However, in this case, the light-emitting layer EL may be spaced apart from an upper portion of the side surface of the second conductive layer AXE2 adjacent to the third conductive layer AXE3.

The light-emitting layer EL may disposed on the third conductive layer AXE3. As each of the first and second ends X1 and X2 have an inclination, the light-emitting layer EL may not extend toward the first and second ends X1 and X2. As the third conductive layer AXE3 has a curved line in a cross-sectional view, the light-emitting layer EL may have a curved line in a cross-sectional view. In an embodiment, the light-emitting layer EL disposed on the third conductive layer AXE3 may have a semicircle shape in a cross-sectional view. Alternatively, the light-emitting layer EL disposed on the third conductive layer AXE3 may have a substantially flat upper surface.

Portions of the light-emitting layer EL may be disconnected from each other by the auxiliary electrode. For example, the light-emitting layer EL adjacent to the first and second conductive layers AXE1 and AXE2 may be disconnected with the light-emitting layer EL adjacent to the third conductive layer AXE3. The light-emitting layer EL adjacent to the first and second conductive layers AXE1 and AXE2 may be fill a portion of each of the first and second openings OP1 and OP2. In addition, The light-emitting layer EL adjacent to the first and second conductive layers AXE1 and AXE2 may be disposed on a side surface of the first organic layer VIA1 located under the auxiliary electrode AXE.

The common electrode CE may be disposed on the light-emitting layer EL. The common electrode CE may include a metal, an alloy, a conductive metal oxide, a transparent conductive material, and the like. For example, the common electrode CE may include a aluminum, a platinum, a silver, a magnesium, a gold, a chromium, a tungsten, a titanium, and the like. Thes may be used in alone or in combination with each other.

The common electrode CE may be disposed on an upper surface of each of the first conductive layer AXE1 and the light-emitting layer EL. For example, the common electrode CE may cover the light-emitting layer EL on the first conductive layer AXE1. In addition, the common electrode CE may cover a portion of the first conductive layer AXE1 which the light-emitting layer EL does not cover.

The common electrode CE may contact a side surface of the second conductive layer AXE2. The common electrode CE may contact a side surface of the second conductive layer AXE2 adjacent to a portion of the first conductive layer AXE1 which the second conductive layer AXE2 contacts.

The common electrode CE may disposed on the third conductive layer AXE3. For example, a portion of the common electrode CE may contact an upper surface of the light-emitting layer EL disposed on the third conductive layer AXE3. In an embodiment, as the light-emitting layer EL has a curved line in a cross-sectional view, the common electrode CE may have a curved line in a cross-sectional view. Alternatively, the common electrode CE disposed on the third conductive layer AXE3 may have a substantially flat upper surface.

Portions of the common electrode CE may be disconnected from each other by the auxiliary electrode AXE. For example, the common electrode CE adjacent to the first and second conductive layers AXE1 and AXE2 may be disconnected with the common electrode CE adjacent to the third conductive layer AXE3. The common electrode CE adjacent to the first and second conductive layers AXE1 and AXE2 may overlap the first and second openings OP1 and OP2. In addition, the common electrode CE adjacent to the first and second conductive layers AXE1 and AXE2 may overlap a side surface of a portion of the first organic layer VIA1 located under the auxiliary electrode.

A light-emitting element LED may include the pixel electrode PE, the light-emitting layer EL, and the common electrode CE. The light-emitting element LED may emit a light. The light-emitting element LED may be included in the sub-pixels which emit light.

As describe above, the display device (e.g., the display device DD in FIG. 1) may include the auxiliary electrode AXE including the first conductive layer AXE1, the second conductive layers AXE2 disposed on the first conductive layer AXE1, the third conductive layer AXE3 whose opposite ends are bent toward the substrate SUB. In addition, an upper surface of the first conductive layer AXE1 and a side surface of the second conductive layer AXE2 may contact the common electrode CE. Accordingly, as the auxiliary electrode AXE may assist a role of lines to which the first power voltage is applied, the voltage drop (IR drop) phenomenon may decrease, and a display quality of the display device may improve.

A common layer may be further disposed on and under the light-emitting layer EL. For example, the common layer may be disposed between the light-emitting layer EL and the common electrode CE. In addition, the common layer may be disposed between the light-emitting layer EL and the pixel electrode PE. The common layer may include an electron injection layer, an electron transport layer, a hole transport layer, and a hole injection layer. In an embodiment, the hole injection layer, the hole transport layer, the light-emitting layer EL, the electron transport layer, and the electron injection layer may be arranged in the third direction DR3 in that order. Alternatively, the electron injection layer, the electron transport layer, the light-emitting layer EL, the hole transport layer, and the hole injection layer may be arranged in the third direction DR3 in that order. However, the present disclosure may not be limited to this.

The common layer may be disposed on the third conductive layer AXE3. In addition, the common layer may be disposed on the first conductive layer AXE1. In this case, the common layer may be spaced apart from the second conductive layer AXE2.

The encapsulation layer TFE may be disposed on the common electrode CE. The encapsulation layer TFE may cover the light-emitting element LED. The encapsulation layer TFE may seal the display area DA and protect the light-emitting element LED from impurities from outside.

The encapsulation layer TFE may include at least one inorganic encapsulation layer and at least one organic encapsulation layer. The inorganic encapsulation layer may include a inorganic insulating material. For example, the inorganic insulating material may include a silicon nitride, a silicon oxide, a silicon oxynitride, and the like. These may be used in alone or in combination with each other. In addition, the organic encapsulation layer may include an organic insulating material such as a polyimide.

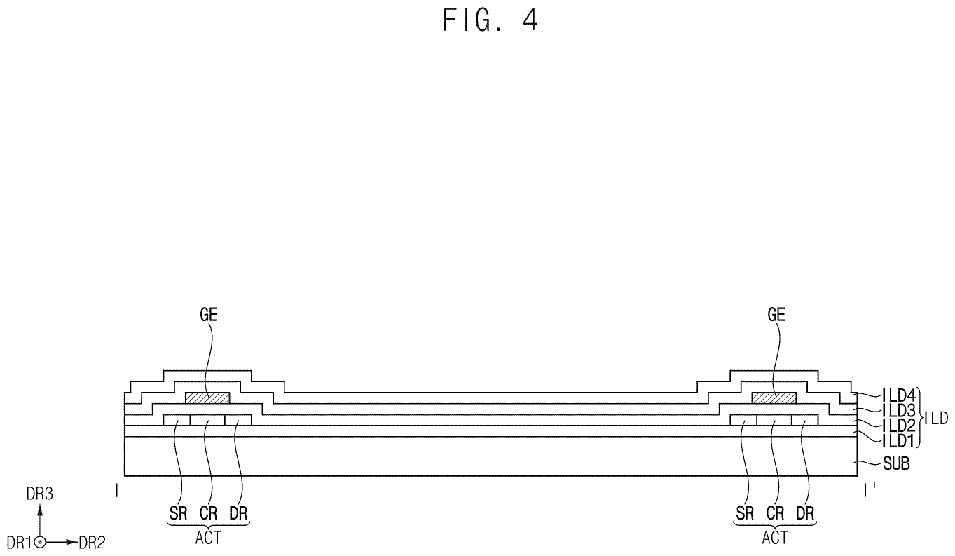

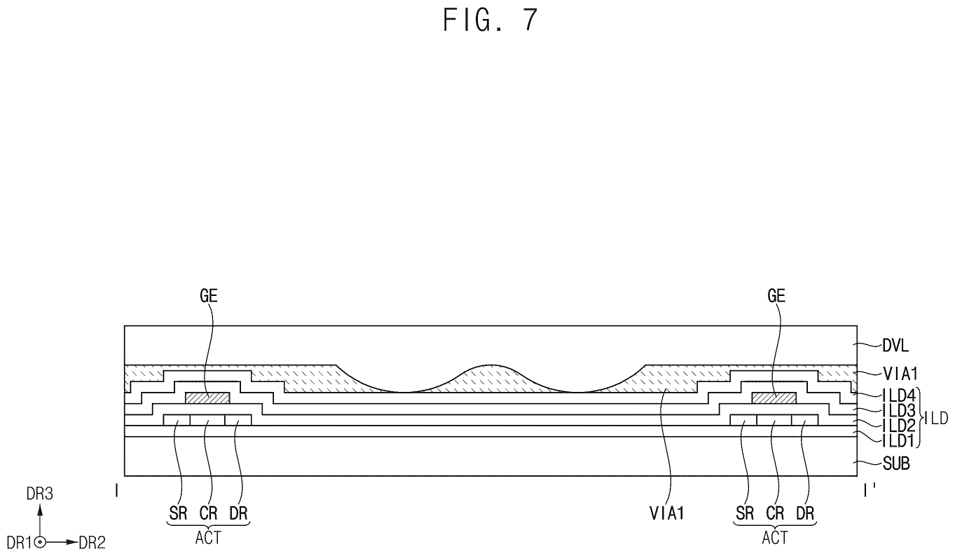

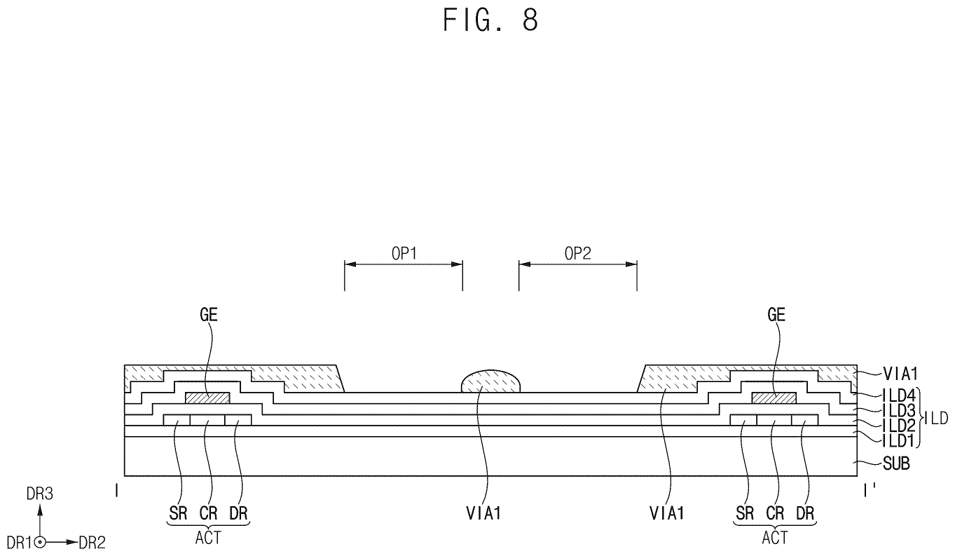

FIGS. 4, 5, 6, 7, 8, 9, 10, 11, 12, 13, 14, 15, 16, 17, 18, 19, 20, 21, 22, and 23 are cross-sectional views illustrating a method of manufacturing the display device in FIG. 1.

Referring to FIG. 4, the inorganic insulating layer ILD may be formed on the substrate SUB. The inorganic insulating layer ILD may include the first inorganic insulating layer ILD1, the second inorganic insulating layer ILD2, the third inorganic insulating layer ILD3, and the fourth inorganic insulating layer ILD4. The first inorganic insulating layer ILD1, the second inorganic insulating layer ILD2, the third inorganic insulating layer ILD3, and the fourth inorganic insulating layer ILD4 may be laminated on the substrate SUB in that order.

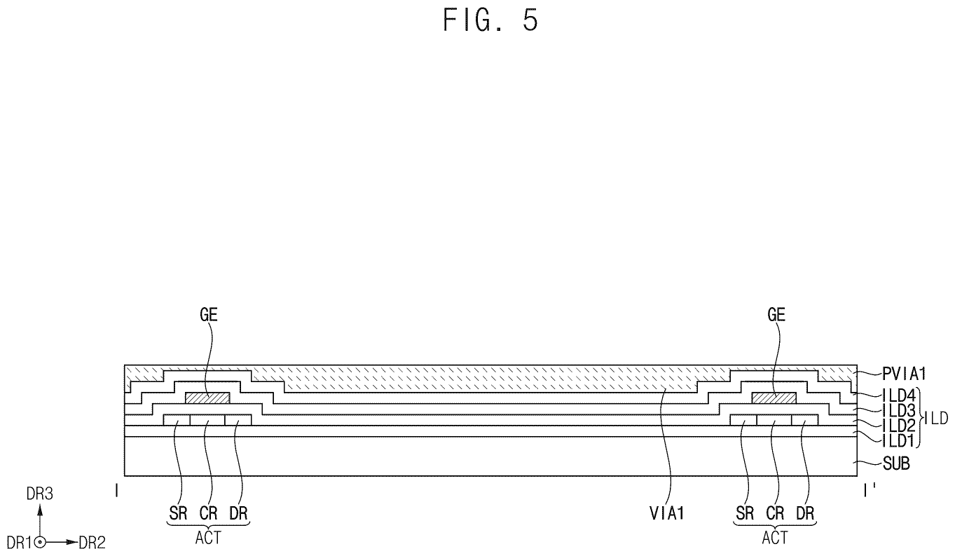

Referring to FIG. 5, A first preliminary organic layer VIA1 may be formed on the fourth inorganic insulating layer ILD4. The first preliminary organic layer PVIA1 may cover a step formed around the gate electrode GE. An upper surface of the first preliminary organic layer PVIA1 may be substantially flat. The first preliminary organic layer PVIA1 may include an organic insulating material such as a polyimide.

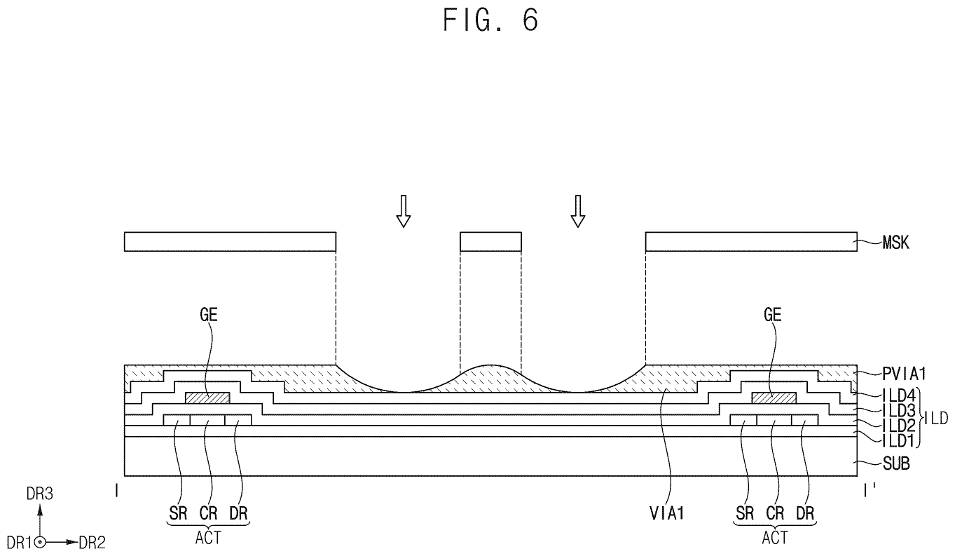

Referring to FIGS. 6, 7, and 8, a light may be irradiated to a portion of the first preliminary organic layer PVIA1. For example, the light transmitted through an opening in a mask MSK may be irradiated to a portion of the first preliminary organic layer PVIA1. A location of the opening in the mask MSK may correspond to a location of the first and second openings OP1 and OP2 of the first preliminary organic layer PVA1. A portion of the first preliminary organic layer PVIA1 may be removed through the light the light irradiated to the first preliminary organic layer PVIA1 through the opening of the mask MSK. That is, a exposing process may be performed on the first preliminary organic layer PVA1.

After the exposing process, a developer DVL may be deposited on a portion of the first preliminary organic layer PVIA1. A portion of the first preliminary organic layer PVIA1 irradiated by the light may be easily response to the developer DVL. For example, a portion of the first preliminary organic layer PVIA1 irradiated by the light may have solubility with improved solubility in the developer DVL. Accordingly, the portion of the first preliminary organic layer PVIA1 irradiated by the light may be dissolved in the developer DVL and completely removed.

A portion of the first preliminary organic layer PVIA1 may be completely removed through the developer DVL to form the first organic layer VIA1. The area where a portion of the first preliminary organic layer PVIA1 is completely removed through the developer DVL and an upper surface of the fourth inorganic insulating layer ILD4 is exposed may be defined as the first opening OP1 and the second opening OP2.

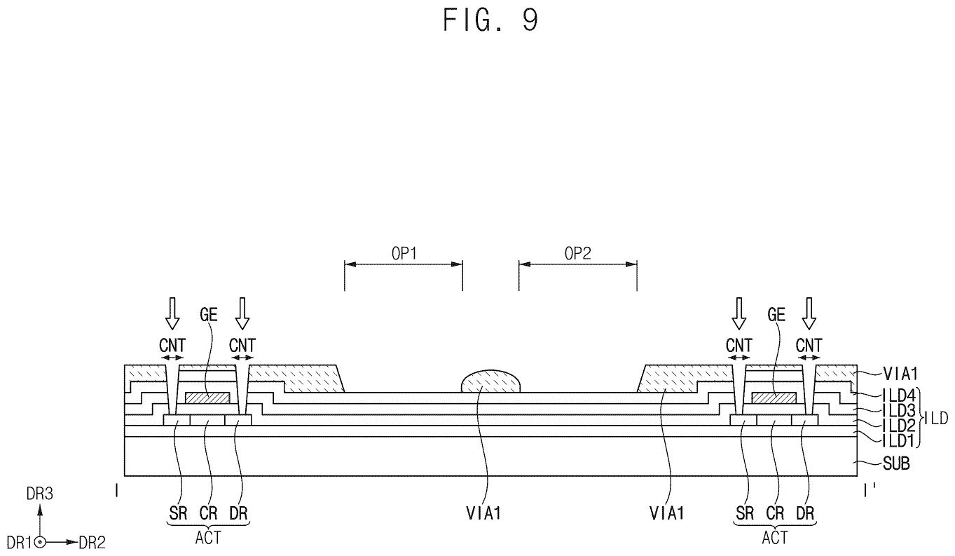

Referring to FIG. 9, contact holes CNT may be defined as a portion of each of the second inorganic insulating layer ILD2, third inorganic insulating layer ILD3, fourth inorganic insulating layer ILD4, and first organic layer VIA1 is removed through an etching process. Specifically, the contact holes CNT may penetrate in third direction DR3 each of the second inorganic insulating layer ILD2, the third inorganic insulating layer ILD3, the fourth inorganic insulating layer ILD4, and the first organic layers VIA1 adjacent to the gate electrode GE in the second direction DR2. At least a portion of an upper surface of the active layer ACT may be exposed through the contact holes CNT. For example, the source region SR and drain region DR of the active layer ACT may be exposed through the contact holes CNT.

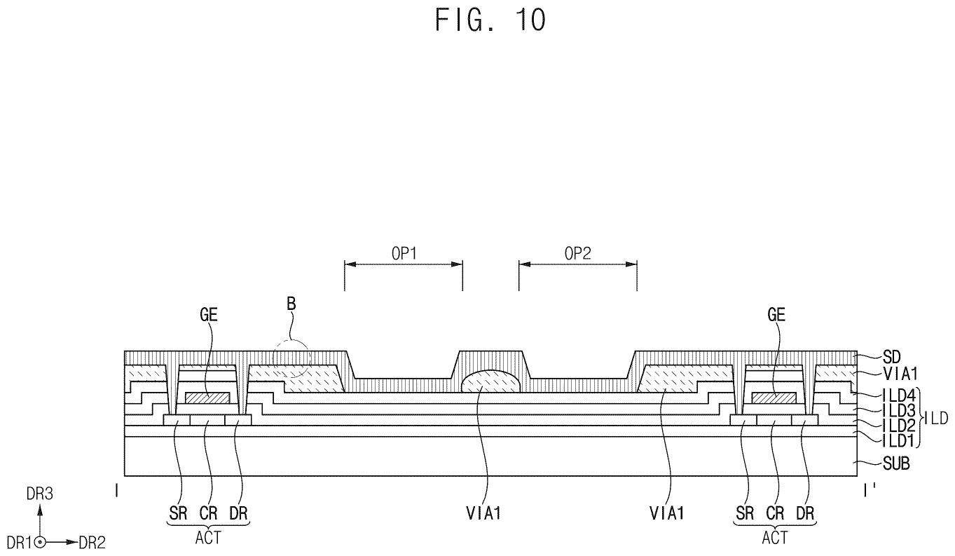

Referring to FIGS. 9 and 10, a metal layer SD may be formed on the first organic layer VIA1. The metal layer SD may fill the contact holes CNT. Accordingly, a portion of the metal layer SD may contact the source region SR and the drain region DR.

The metal layer SD may fill the first opening OP1 and the second opening OP2. For example, the metal layer SD may cover each of a portion of an upper surface and side surface of the first organic layer VIA1, and an upper surface of the fourth inorganic insulating layer ILD4 exposed by the first opening OP1 and the second opening OP2.

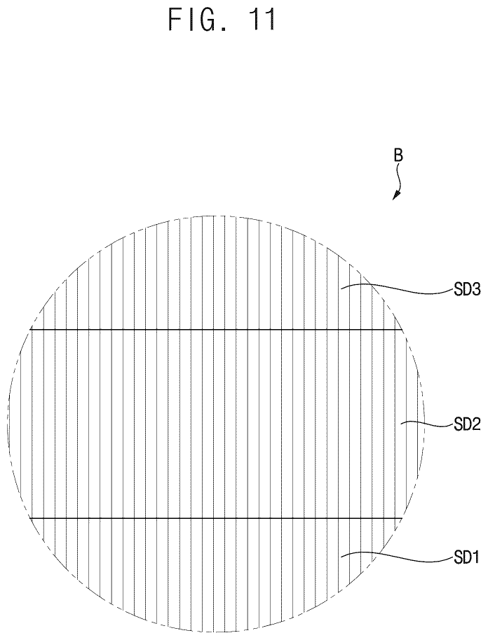

Referring to FIG. 11, an area B is an enlarged cross-sectional view of the metal layer SD. The metal layer SD may include a first metal layer SD1, a second metal layer SD2, and a third metal layer SD3. That is, the first metal layer SD1 may be formed on the first organic layer VIA1, the second metal layer SD2 may be formed on the first metal layer SD1, and the third metal layer SD3 may be formed on the second metal layer SD2.

In an embodiment, the first metal layer SD1 may include a conductive material. For example, the conductive material may include a titanium, a copper, a indium tin oxide, a indium zinc oxide, and the like. These may be used in alone or in combination with each other.

In an embodiment, the second metal layer SD2 may include a conductive material. For example, the conductive material may include an aluminum, a copper, a indium tin oxide, a indium zinc oxide, and the like. These may be used in alone or in combination with each other.

In an embodiment, the third metal layer SD3 may include a conductive material. For example, the conductive material may include a titanium, a copper, a indium tin oxide, a indium zinc oxide, and the like. These may be used in alone or in combination with each other.

In an embodiment, the third metal layer SD3 may include the same material as the first metal layer SD1. Alternatively, the third metal layer SD3 may include a material different from the first metal layer SD1. In addition, in an embodiment, the third metal layer SD3 may include a different material from the second metal layer SD2. For example, the first metal layer SD1 may include a titanium, the second metal layer SD1 may include an aluminum, and the third metal layer SD3 may include a titanium. However, the present disclosure may not be limited to this.

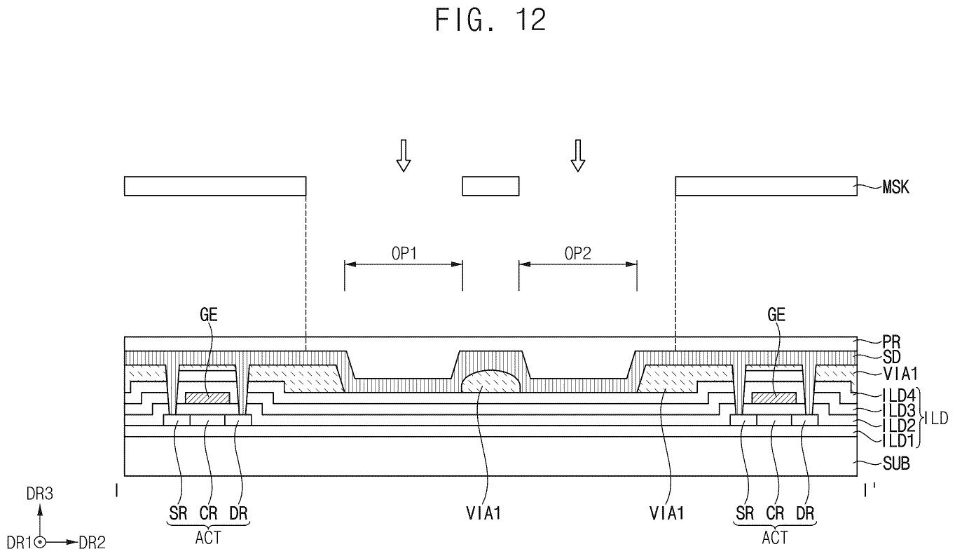

Referring to FIG. 12, a photoresist PR may be formed on the metal layer SD. A exposing process may be performed on the photoresist PR. For example, a light may be irradiated into a portion of the photoresist PR. A portion of the photoresist PR located corresponding to the opening of the mask MSK may be removed by the irradiated light.

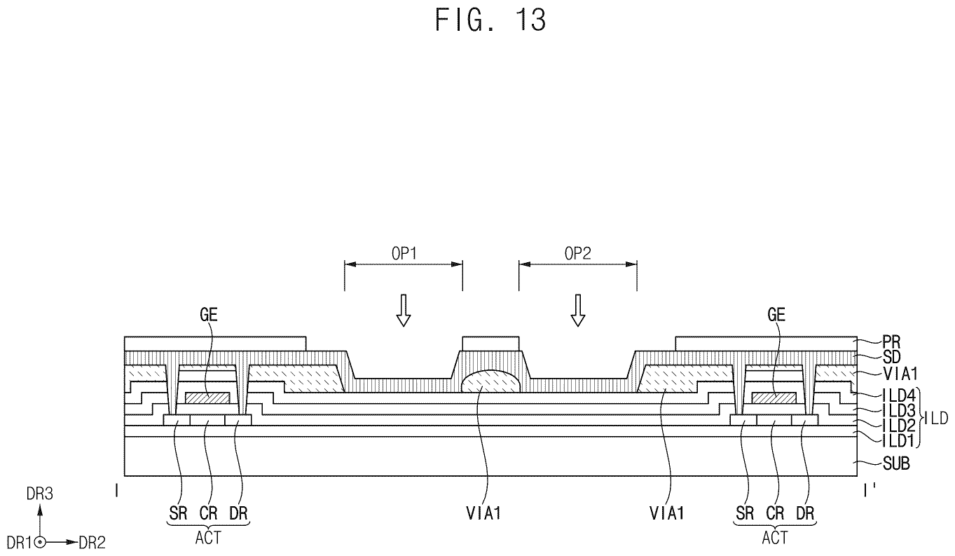

Referring to FIG. 13, a portion of the photoresist PR which is not removed by the light may be disposed on the metal layer SD. The photoresist PR which is not removed may overlap the active layer ACT. In addition, the photoresist PR which is not removed may overlap a portion located between the first opening OP1 and the second opening OP2 of the first organic layer VIA1.

In an embodiment, the photoresist PR may be a positive photoresist. In this case, an etching process may be performed after the exposing process to remove a portion of the metal layer SD which does not overlap the photoresist PR.

Alternatively, the photoresist PR may be a negative photoresist. In this case, an etching process may be performed after the exposing process to remove a portion of the metal layer SD overlapping the photoresist PR.

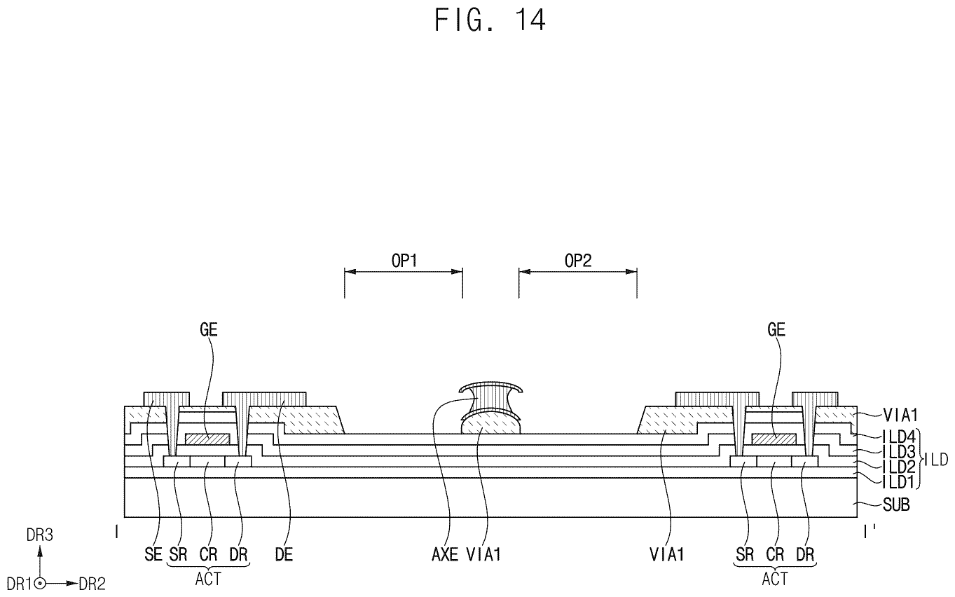

Referring to FIG. 14, through the etching process, the source electrode SE, the drain electrode DE, and the auxiliary electrode AXE may be formed on the first organic layer VIA. The source electrode SE and drain electrode DE may contact a portion of the active layer ACT.

The auxiliary electrode AXE may be formed on a portion located between the first opening OP1 and the second opening OP2 of the first organic layer VIA1. The auxiliary electrode AXE may have a three-layer structure corresponding to each of the first to third metal layers (e.g., the first to third metal layers SD1, SD2, and SD3 in FIG. 11). In addition, an additional etching process may be performed on the auxiliary electrode AXE so that the second conductive layer (e.g., the second conductive layer AXE2 in FIG. 3) has an undercut shape in a cross-sectional view.

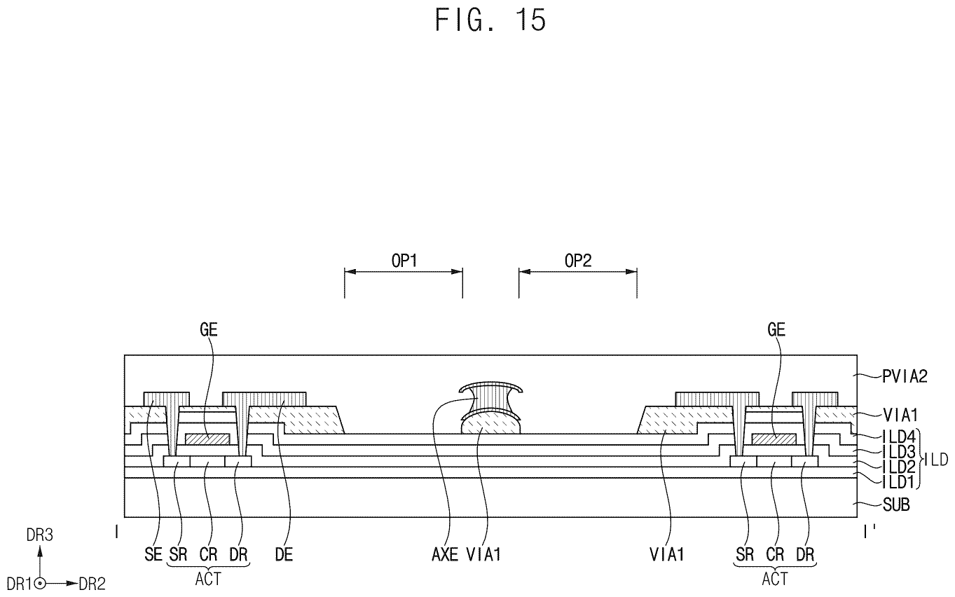

Referring to FIG. 15, a second preliminary organic layer PVIA2 may be formed on the source electrode SE, the drain electrode DE, and the auxiliary electrode AXE. The second preliminary organic layer PVIA2 may fill the first opening OP1 and the second opening OP2. The second preliminary organic layer PVIA2 may have a substantially flat upper surface. The second preliminary organic layer PVIA2 may include an organic insulating material such as polyimide.

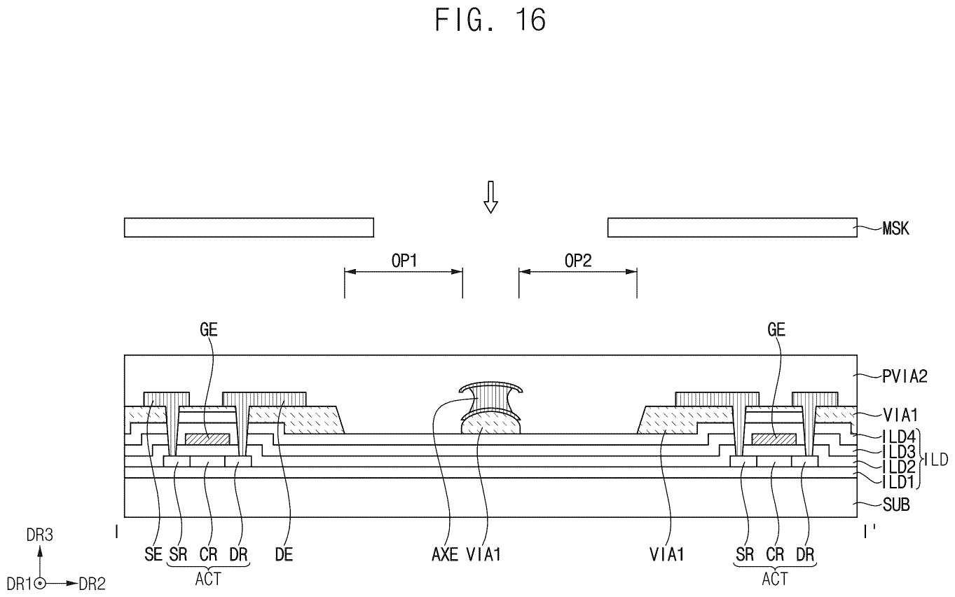

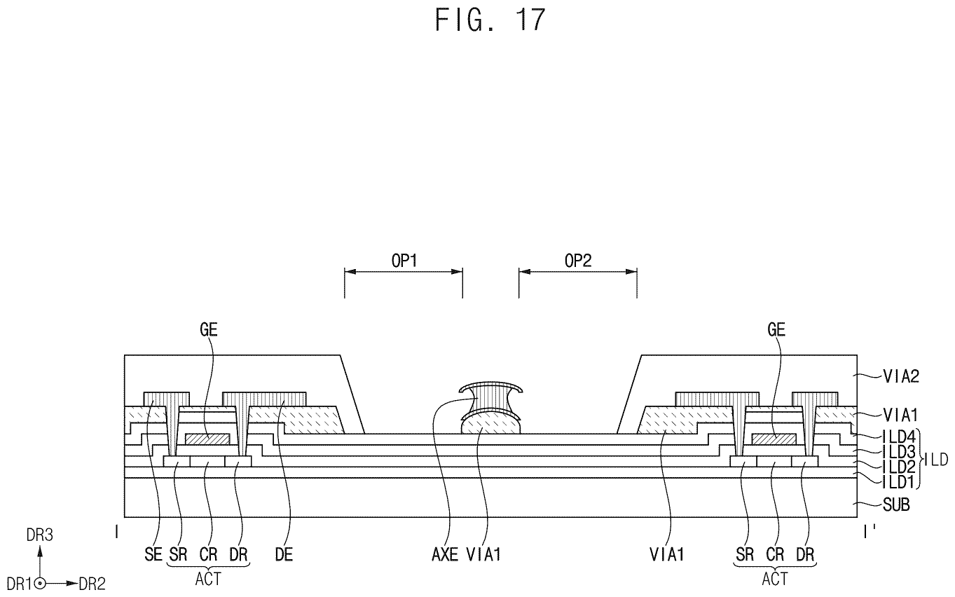

Referring to FIGS. 16 and 17, an exposure process and an etching process may be performed on the second preliminary organic layer PVIA2. Accordingly, a portion of the second preliminary organic layer PVIA2 may be removed to form the second organic layer VIA2 in which an opening, through which the fourth inorganic insulating layer ILD4 and the auxiliary electrode AXE are exposed, is defined. A portion of the second preliminary organic layer PVIA2 adjacent to the auxiliary electrode AXE may be removed, so that the auxiliary electrode AXE may be spaced apart from the second organic layer VIA2.

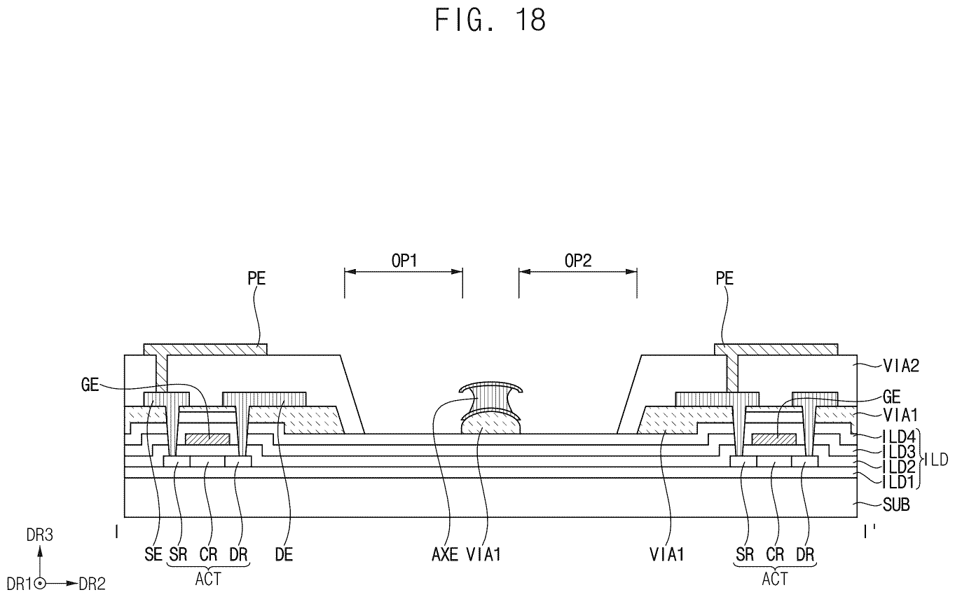

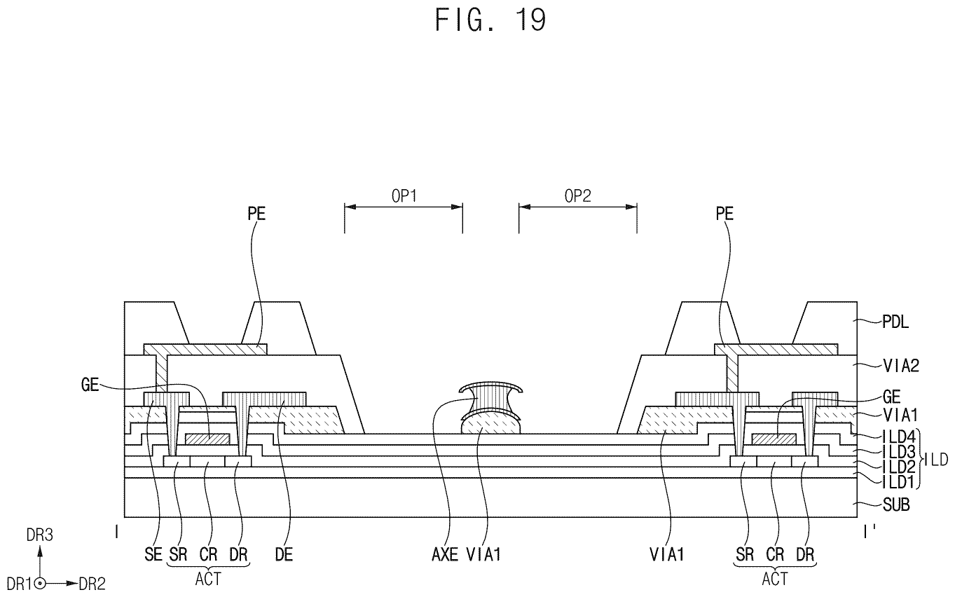

Referring to FIGS. 18 and 19, the pixel electrode PE may be formed on the second organic layer VIA2. In an embodiment, a portion of the second organic layer VIA2 may be removed through an etching process to expose an upper surface of the source electrode SE. The pixel electrode PE may contact the exposed upper surface of the source electrode SE. Alternatively, a portion of the second organic layer VIA2 may be removed through an etching process to expose an upper surface of the drain electrode DE. The pixel electrode PE may contact the exposed upper surface of the drain electrode DE.

The pixel-defining layer PDL may be formed on the pixel electrode PE. The pixel-defining layer PDL may include the same material as the first organic layer VIA1. For example, the pixel-defining layer PDL may include an organic insulating material such as polyimide. A portion of the pixel-defining layer PDL may be removed to define an opening exposing an upper surface of the pixel electrode PE.

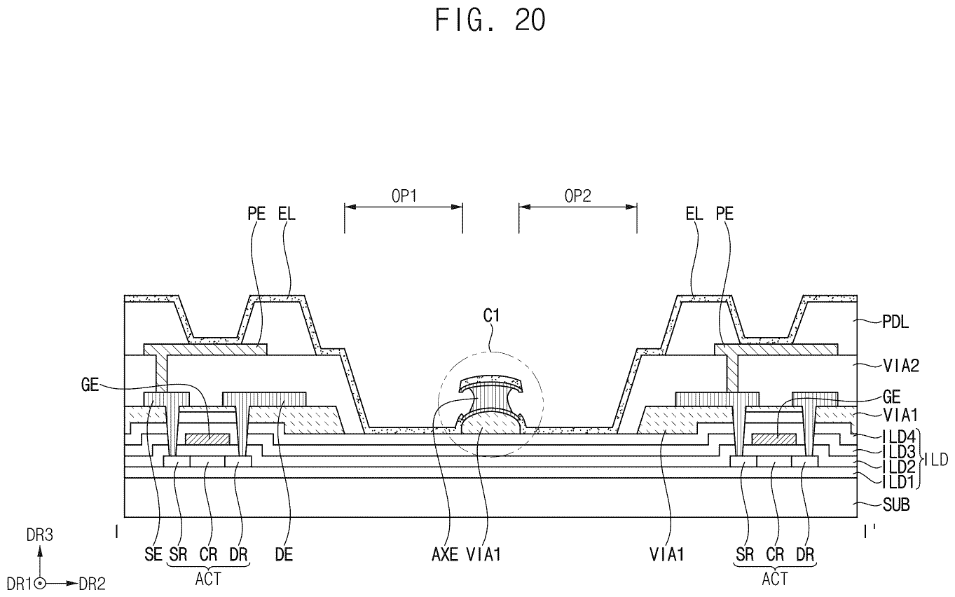

Referring to FIG. 20, the light-emitting layer EL may be formed on the pixel-defining layer PDL, a pixel electrode PE, a second organic layer VIA2, and a auxiliary electrode AXE. The light-emitting layer EL may cover entirely the pixel-defining layer PDL, a pixel electrode PE, a second organic layer VIA2, and a auxiliary electrode AXE.

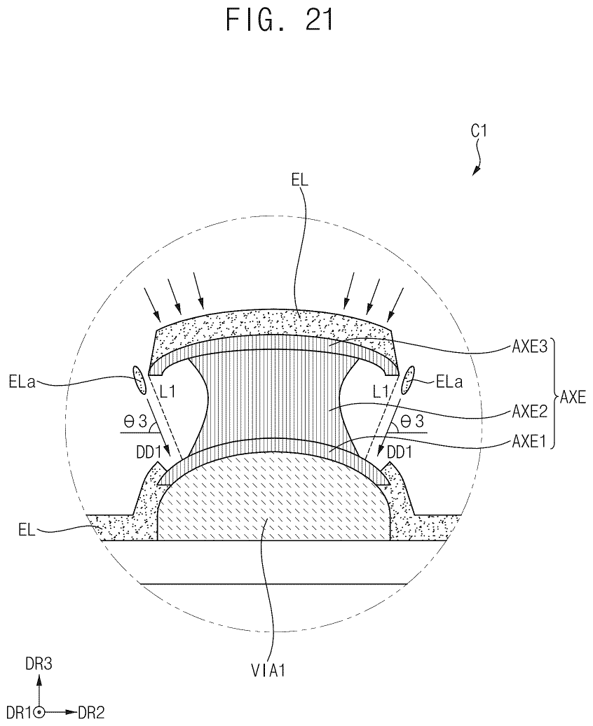

FIG. 21 is an enlarged cross-sectional view of an area C1. Referring to FIG. 21, a light-emitting material ELa forming the light-emitting layer EL may be incident in a first deposition direction DD1. The light-emitting material ELa may be incident on the pixel-defining layer PDL, the pixel electrode PE, the second organic layer VIA2, and the auxiliary electrode AXE in the first deposition direction DD1 to form the light-emitting layer EL.

The first deposition direction DD1 may form a third inclination angle θ3 with respect to the second direction DR2 or a direction opposite to the second direction DR2. The light-emitting material ELa may be incident symmetrically with respect to the second conductive layer AXE2. For example, the light-emitting material ELa may form the third inclination angle θ3 with respect to the second direction DR2, and may be entirely deposited on the pixel-defining layer PDL, the pixel electrode PE, the second organic layer VIA2, and the auxiliary electrode AXE. In addition, the light-emitting material ELa may form the third inclination angle θ3 with respect to a direction opposite to the second direction DR2.

As the opposite ends of the third conductive layer AXE3 are bent in a direction opposite to the third direction DR3, the light-emitting material ELa may not be deposited on a side surface of the second conductive layer AXE2. In an embodiment, a first straight line L1 which extend from one of the opposite ends of the third conductive layer AXE3 and is parallel to the first deposition direction DD1 may not intersect the side surface of the second conductive layer AXE2.

Specifically, when the light-emitting material ELa is incident in a direction forming the third inclination angle θ3 with respect to a direction opposite to the second direction DR2, the light-emitting material ELa is incident in the second direction DR2 from the pixel electrode PE toward the auxiliary electrode AXE. In this case, the light-emitting layer EL is deposited on a portion of an upper surface of the first conductive layer AXE1, however the light-emitting material ELa may not be deposited on the side surface of the second conductive layer AXE2. In the case that the light-emitting material ELa is incident in a direction forming the third inclination angle θ3 with respect to the second direction DR2, and the traveling direction of depositing the light-emitting material ELa is opposite to the second direction DR2, the light-emitting material ELa may not be deposited to the surface of the second auxiliary layer AXE2.

The light-emitting layer EL may be disposed on the third conductive layer AXE3. In the case that the third conductive layer AXE3 has a curve line in a cross-sectional view, the light-emitting layer EL may have a curve line in a cross-sectional view.

As the opposite ends of the third conductive layer AXE3 are bent toward the substrate SUB, portions of the light-emitting layer EL may be disconnected from each other by the auxiliary electrode AXE. For example, the light-emitting layer EL deposited on the second conductive layer AXE2 may be disconnected from the light emitting layer EL deposited on the third conductive layer AXE3.

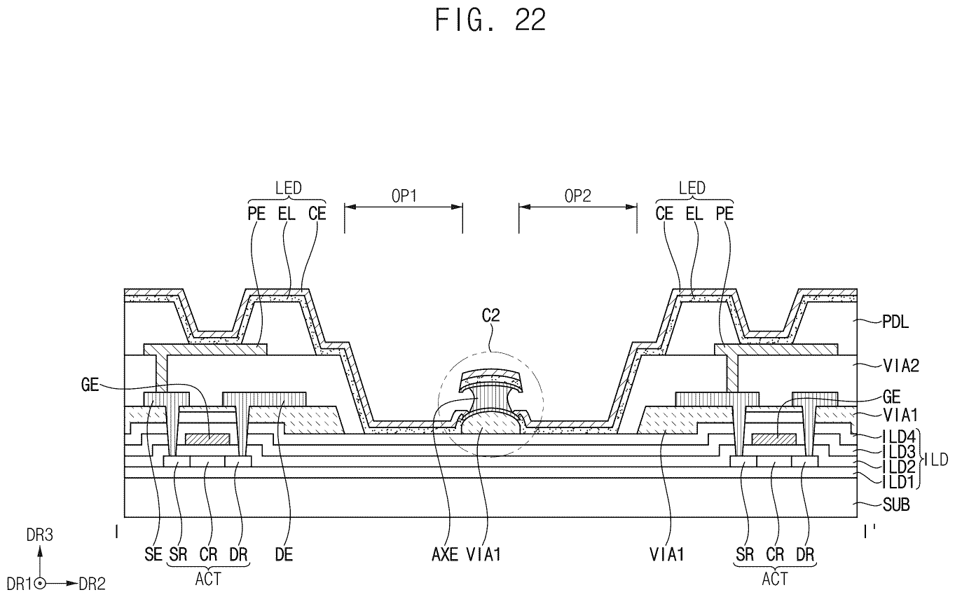

Referring to FIG. 22, the common electrode CE may be formed on the light-emitting layer EL. The common electrode CE may entirely cover the light-emitting layer EL.

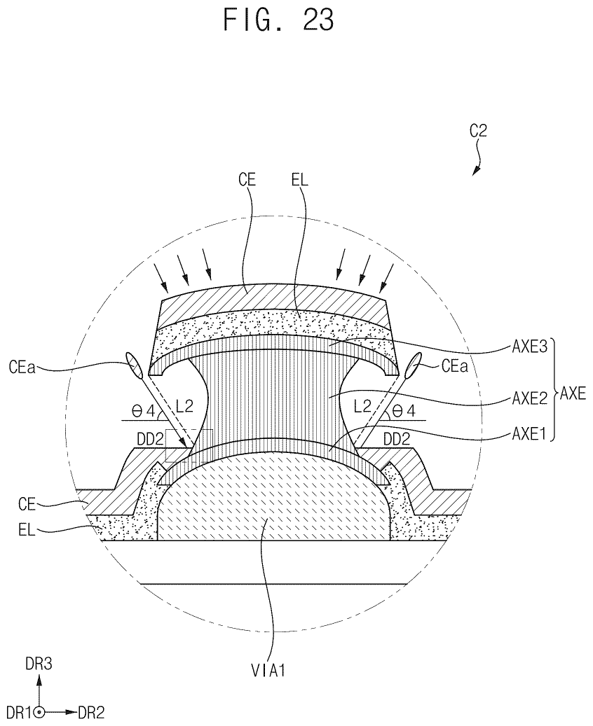

FIG. 23 is an enlarged cross-sectional view of an area C2 in FIG. 22. Referring to FIG. 23, a metal material CEa forming the common electrode CE may be incident in a second deposition direction DD2. The metal material CEa may be incident on the light-emitting layer EL in the second deposition direction DD2 to form the common electrode CE.

The second deposition direction may form a fourth inclination angle 04 with respect to the second direction DR2 or a direction opposite to the second direction DR2. The common electrode CE may be symmetrically incident on the second conductive layer AXE2. For example, the metal material CEa may be deposited on the light-emitting layer EL in a direction forming the fourth inclination angle θ4 with respect to the second direction DR2. In addition, the metal material CEa may form the fourth inclination angle θ4 with respect to a direction opposite to the second direction DR2.

In an embodiment, the fourth inclination angle θ4 may be smaller than the third inclination angle θ3. Accordingly, a second straight line L2, which extends from one of the opposite ends of the third conductive layer AXE3 and is parallel to the second deposition direction DD2, may intersect the side surface of the second conductive layer AXE2. That is, the metal material CEa may be incident in the second deposition direction DD2 and deposited on the side of the second conductive layer AXE2. Accordingly, as the common electrode CE contacts the side surface of the second conductive layer AXE2, current may flow through the auxiliary electrode AXE.

The common electrode CE may overlap the third conductive layer AXE3. For example, the common electrode CE may be deposited on the light-emitting layer EL formed on the third conductive layer AXE3. When the light-emitting layer EL formed on the third conductive layer AXE3 has a curve in its cross-sectional view, the common electrode CE may also have a curve in its cross-sectional view.

However, as the opposite ends of the third conductive layer AXE3 are bent toward the substrate SUB, portions of the common electrode CE may be disconnected from each other by the auxiliary electrode AXE. For example, the common electrode CE deposited on the second conductive layer AXE2 may be disconnected from the common electrode CE deposited on the third conductive layer AXE3.

An encapsulation layer (e.g., the encapsulation layer TFE in FIG. 2) may be formed on the common electrode CE. Accordingly, the display device in FIG. 1 (e.g., the display device DD in FIG. 1) may be manufactured.

As described above, as the method of manufacturing the display device is to deposit the metal material CEa by adjusting the incident angle of the metal material CEa used for deposition of the common electrode CE on the third conductive layer AXE3 whose opposite ends are bent toward the substrate SUB, the auxiliary electrode AXE may be manufactured without any additional processes. Therefore, the process time may be shortened and the process cost may be reduced.

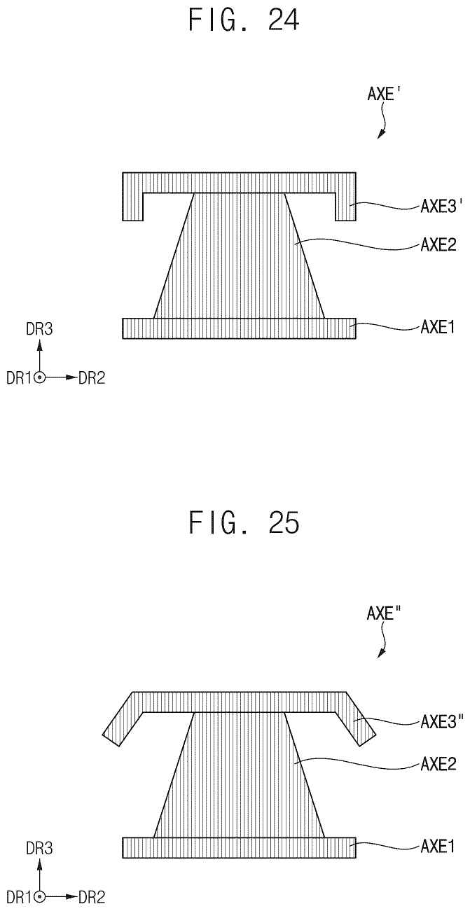

FIG. 24 is a cross-sectional view illustrating an example of an auxiliary electrode in FIG. 2.

An auxiliary electrode AXE′ in FIG. 24 is substantially equal to the auxiliary electrode AXE in FIGS. 2 and 3 except for a shape of a third conductive layer AXE3′.

Hereinafter, descriptions that overlap with the components of the display device DD described with reference to FIGS. 2 and 3 will be omitted or simplified.

Referring to FIG. 24, an auxiliary electrode AXE' may include a third conductive layer AXE3′. A shape of the third conductive layer AXE3′ may be a partial rectangular shape in a cross-sectional view. Opposite ends of a third conductive layer AXE3′ may face a direction opposite to the third direction DR3. In addition, the opposite ends of the third conductive layer AXE3′ may be parallel to the third direction DR3.

FIG. 25 is a cross-sectional view illustrating another example of an auxiliary electrode in FIG. 2.

An auxiliary electrode AXE″ in FIG. 25 is substantially equal to the auxiliary electrode AXE in FIGS. 2 and 3 except for a shape of a third conductive layer AXE3″.

Hereinafter, descriptions that overlap with the components of the display device DD described with reference to FIGS. 2 and 3 will be omitted or simplified.

Referring to FIG. 25, an auxiliary electrode AXE″ may include a third conductive layer AXE3″. A shape of the third conductive layer AXE3″ may be a partial hexagonal in a cross-sectional view. Opposite ends of the third conductive layer AXE3″ may face a direction opposite to the third direction DR3. In addition, the opposite ends of the third conductive layer AXE3″ may face in a direction opposite to a direction toward the second conductive layer AXE2.

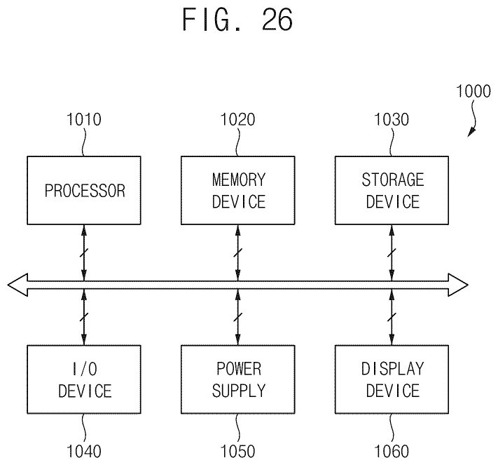

FIG. 26 is a block diagram illustrating an electronic device according to an embodiment.

Referring to FIG. 26, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

The display device and the method of manufacturing the same according to the embodiments may be applied to an electronic device included in a computer, a notebook, a mobile phone, a smartphone, a smart pad, a PMP, a PDA, an MP3 player, or the like.

Although the display device and the method of manufacturing the same according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a first organic layer disposed on a substrate, and in which a first opening and a second opening spaced apart from the first opening are defined;
an auxiliary electrode disposed on a portion of the first organic layer located between the first opening and the second opening, and including:
a first conductive layer which contacts the portion of the first organic layer;
a second conductive layer disposed on the first conductive layer; and
a third conductive layer disposed on the second conductive layer and whose opposite ends are bent toward the substrate;
a light-emitting layer disposed on the first organic layer and the auxiliary electrode, wherein portions of light-emitting layer are disconnected from each other by the auxiliary electrode; and
a common electrode disposed on the light-emitting layer, wherein portions of the common electrode are disconnected from each other by the auxiliary electrode.

2. The display device of claim 1, wherein a first inclination angle formed by a first tangent which is tangential to a first end of an upper surface of the third conductive layer and a plane parallel to a major surface of the substrate is substantially equal to a second inclination angle formed by a second tangent which is tangential to a second end of an upper surface of the third conductive layer and the plane parallel to a major surface of the substrate.

3. The display device of claim 2, wherein each of the first inclination angle and the second inclination angle is about 10 degrees to about 150 degrees.

4. The display device of claim 1, wherein the third conductive layer forms an undercut shape with the second conductive layer.

5. The display device of claim 1, wherein the portions of the light-emitting layer contact a portion of an upper surface of the first conductive layer and an upper surface of the third conductive layer, respectively, and are spaced apart from each other with a side surface of the second conductive layer therebetween.

6. The display device of claim 5, wherein the common electrode contacts a portion of the side surface of the second conductive layer, and overlaps the light-emitting layer, which contacts the upper surface of the third conductive layer.

7. The display device of claim 1, wherein an upper surface of the portion of the first organic layer, which contacts the first conductive layer, has a curved surface.

8. The display device of claim 7, wherein each of the first conductive layer and the third conductive layer has a curved line corresponding to the curved surface in a cross-sectional view.

9. The display device of claim 1, wherein the first conductive layer, the second conductive layer, and the third conductive layer include different materials from each other.

10. The display device of claim 1, further comprising:
a transistor including an active layer disposed on the substrate, a gate electrode disposed on the active layer, and a source electrode and a drain electrode which contact the active layer; and
a second organic layer disposed on the transistor and spaced apart from the auxiliary electrode.

11. The display device of claim 10, wherein the auxiliary electrode is disposed in a same layer as each of the source electrode and the drain electrode, and includes a same material as each of the source electrode and the drain electrode.

12. A method of manufacturing a display device, the method comprising:
forming an inorganic insulating layer on a substrate;
forming a first organic layer, in which a first opening and a second opening spaced apart from each other are defined, on the inorganic insulating layer;
forming a first conductive layer on the first organic layer;
forming a second conductive layer on the first conductive layer;
forming an auxiliary electrode by forming a third conductive layer, whose opposite ends are bent toward the substrate, on the second conductive layer;
forming a light-emitting layer on the first organic layer and the auxiliary electrode, wherein portions of light-emitting layer are disconnected from each other by the auxiliary electrode; and
forming a common electrode on the light-emitting layer, wherein portions of the common electrode are disconnected from each other by the auxiliary electrode.

13. The method of claim 12, wherein the forming of the first organic layer includes:
forming a preliminary organic layer on the inorganic insulating layer;
exposing the first preliminary organic layer to a light; and
forming the first opening and the second opening by removing a portion of the preliminary organic layer through a developer.

14. The method of claim 13, wherein the forming of the auxiliary electrode includes:
forming a metal layer, which fills the first opening and the second opening, on the first organic layer; and
forming a source electrode, a drain electrode, and the auxiliary electrode simultaneously on the first organic layer by removing a portion of the metal layer.

15. The method of claim 14, wherein the forming of the metal layer includes:
forming a first metal layer, which fills the first opening and the second opening, on the first organic layer;
forming a second metal layer including a material different from the first metal layer on the first metal layer; and
forming a third metal layer including a material different from the second metal layer on the second metal layer.

16. The method of claim 15, wherein the first conductive layer is formed by removing a portion of the first metal layer, the second conductive layer is formed by removing a portion of the second metal layer, and the third conductive layer is formed by removing a portion of the third metal layer.

17. The method of claim 13, wherein the forming of the light-emitting layer includes depositing a light-emitting material forming the light-emitting layer in a first deposition direction having a first inclination angle with respect to a plane parallel to a major surface of the substrate, and
the forming of the common electrode includes depositing a metal material forming the common electrode in a second deposition direction having a second inclination angle with respect to the plane parallel to the major surface of the substrate.

18. The method of claim 17, wherein a line, which extends from one end among the opposite ends of an upper surface of the third conductive layer and parallel to the first deposition direction, does not intersect with a side surface of the second conductive layer.

19. The method of claim 17, wherein a line, which extends from one end among the opposite ends of an upper surface of the third conductive layer and parallel to the second deposition direction, intersects with a side surface of the second conductive layer.

20. The method of claim 17, wherein the first inclination angle is larger than the second inclination angle.

21. An electronic device comprising:
a display device; and
a power supply configured to provide power to the display device,
wherein the display device comprises:
a first organic layer disposed on a substrate, and in which a first opening and a second opening spaced apart from the first opening are defined;
an auxiliary electrode disposed on a portion of the first organic layer located between the first opening and the second opening, and including:
a first conductive layer which contacts the portion of the first organic layer;
a second conductive layer disposed on the first conductive layer; and
a third conductive layer disposed on the second conductive layer and whose opposite ends are bent toward the substrate;
a light-emitting layer disposed on the first organic layer and the auxiliary electrode, wherein portions of light-emitting layer are disconnected from each other by the auxiliary electrode; and
a common electrode disposed on the light-emitting layer, wherein portions of the common electrode are disconnected from each other by the auxiliary electrode.
